(19) United States
(12) Patent Application Publication
(10) Pub. No.: US 2021/0184108 A1
(43) Pub. Date: Jun. 17, 2021

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Ming ZHOU, Shanghai (CN)

(21) Appl. No.: 17/033,102

(22) Filed: Sep. 25, 2020

(30) Foreign Application Priority Data
Dec. 11, 2019 (CN) 201911269343.7

(51) Int. Cl. H01L 43/12; H01L 43/02; H01L 43/10

(52) U.S. Cl. CPC H01L 43/12; H01L 43/10; H01L 43/02

(57) ABSTRACT

Semiconductor structure and fabrication method are provided. The fabrication method includes: providing a substrate; forming a bottom electromagnetic material film on the substrate; forming a precursor film on the bottom electromagnetic material film; forming a first insulating film on the precursor film; and performing an annealing treatment to form the precursor film into a second insulating film. The performance of the semiconductor structure is improved.

### CROSS-REFERENCES TO RELATED APPLICATION

This application claims the priority of Chinese Patent Application No. 201911269343.7, filed on Dec. 11, 2019, the content of which is incorporated herein by reference in its entirety.

### TECHNICAL FIELD

The present disclosure generally relates to the field of semiconductor manufacturing and, more particularly, to a semiconductor structure and a fabrication method thereof.

### BACKGROUND

An MRAM (i.e., Magnetic Random-Access Memory) is a non-volatile magnetic random-access memory. The MRAM has high-speed read and write capabilities of a static random-access memory (SRAM), high integration of a dynamic random-access memory (DRAM), and power consumption much lower than the DRAM. Compared with a flash memory (Flash), performance of the MRAM will not degrade as use time increases. Due to the above-mentioned characteristics, the MRAM is regarded as a universal memory and is considered to be able to replace the SRAM, the DRAM, an electrically erasable programmable read-only memory (EEPROM), and the Flash.

Different from existing random-access memory chip manufacturing technologies, data in the MRAM is not stored in a form of an electric charge or an electric current, but is stored in a magnetic state, which is sensed by measuring a resistance without disturbing the magnetic state. The MRAM uses a magnetic tunnel junction (MTJ) structure for data storage. An MRAM cell may include a transistor (1T) and a magnetic tunnel junction (MTJ) to form a memory cell. The MTJ structure at least includes two electromagnetic layers and an insulating layer for isolating the two electromagnetic layers. Electric current vertically flows or “passes” from one of the two electromagnetic layers to another of the two electromagnetic layers through the insulating layer. One of the two electromagnetic layers is a fixed magnetic layer, which fixes an electrode in one alternative direction through a strong fixed field. Another of the two electromagnetic layers is a freely rotatable magnetic layer, which holds an electrode in one of alternative directions.

However, there is a need to improve device performance of conventionally formed magnetic tunnel junction.

### SUMMARY

One aspect of the present disclosure provides a method for forming a semiconductor structure. The method includes: providing a substrate; forming a bottom electromagnetic material film on the substrate; forming a precursor film on the bottom electromagnetic material film; and forming a first insulating film on the precursor film.

Optionally, the precursor film is made of a material including magnesium, aluminum, hafnium, zirconium, or a combination thereof.

Optionally, forming the precursor film includes: forming an insulating material film on the bottom electromagnetic material film, that the insulating material film is made of a metal oxide; and performing a modification treatment on the insulating material film to remove oxygen therefrom, to form the insulating material film into the precursor film.

Optionally, a thickness of the insulating material film ranges from about 0 angstroms to about 500 angstroms.

Optionally, the metal oxide is a material including magnesium oxide, aluminum oxide, hafnium dioxide, zirconium dioxide, or a combination thereof.

Optionally, forming the insulating material film includes a chemical vapor deposition process, a physical vapor deposition process, or a combination thereof.

Optionally, the modification treatment includes: performing a reduction treatment on the insulating material film to remove oxygen therefrom, that process parameters of the reduction treatment include: gases including hydrogen and helium, that a flow rate of the hydrogen is from about 50 SCCM to about 5000 SCCM, and a flow rate of the helium is from about 0 SCCM to about 10000 SCCM; a temperature from about 25° C. to about 150° C.; and a treatment time from about 1 second to about 120 minutes.

Optionally, forming the precursor film includes a chemical vapor deposition process, a physical vapor deposition process, or a combination thereof.

Optionally, forming the first insulating film includes a chemical vapor deposition process, a physical vapor deposition process, an atomic layer deposition process, or a combination thereof, and the first insulating film is made of a material including magnesium oxide, aluminum oxide, silicon nitride, silicon oxynitride, hafnium dioxide, zirconium dioxide, or a combination thereof.

Optionally, forming the first insulating film includes: performing an oxidation treatment on the precursor film to form the precursor film into the first insulating film, that a thickness of the first insulating film is less than or equal to a thickness of the precursor film; and the thickness of the first insulating film ranges from about 0 angstroms to about 500 angstroms.

Optionally, the first insulating film is made of a material including magnesium oxide, aluminum oxide, hafnium dioxide, zirconium dioxide, or a combination thereof.

Optionally, the method further includes: forming a top electromagnetic material film on the first insulating film; and before forming the top electromagnetic material film on the first insulating film, performing an annealing treatment to form the precursor film into a second insulating film, that the second insulating film is at a bottom of the first insulating film, and a temperature range of the annealing treatment is from about 300 degrees Celsius to about 400 degrees Celsius.

Optionally, a conductive layer is provided in the substrate, the substrate exposes a surface of the conductive layer, and the bottom electromagnetic material film is on the substrate and the surface of the conductive layer.

Optionally, the bottom electromagnetic material film includes: a lower electrode film on the substrate and the surface of the conductive layer, a lower composite film on the lower electrode film, and a lower electromagnetic film on the lower composite film.

Optionally, the lower electrode film is made of a material including copper, tungsten, aluminum, titanium, titanium nitride, tantalum, or a combination thereof; the lower composite film has a structure including a single layer structure or a composite structure; and the lower electromagnetic film is made of a material including iron, platinum, cobalt, nickel, cobalt iron boron, cobalt iron, nickel iron, lanthanum strontium manganese oxygen, or a combination thereof.

Optionally, when the lower composite film has the single layer structure, the lower composite film is made of a material including iron, platinum, cobalt, nickel, cobalt iron boron, cobalt iron, nickel iron, lanthanum strontium manganese oxygen, or a combination thereof, and when the lower composite film has the composite structure, the lower composite film includes a plurality of conductive layers overlapped each other, and each layer of the plurality of conductive layers is made of a material including iron, platinum, cobalt, nickel, cobalt iron boron, cobalt iron, nickel iron, lanthanum strontium manganese oxygen, or a combination thereof.

Optionally, the top electromagnetic material film includes: an upper electromagnetic film on the first insulating film, an upper composite film on the upper electromagnetic film, and an upper electrode film on the upper composite film.

Optionally, the method further includes: after forming the top electromagnetic material film, patterning the top electromagnetic material film, the first insulating film, the second insulating film, and the bottom electromagnetic material film, until a surface of the substrate is exposed, so that the patterned top electromagnetic material film forms a top electromagnetic layer, the patterned first insulating film forms a first insulating layer, the patterned second insulating film forms a second insulating layer, and the patterned bottom electromagnetic material film forms a bottom electromagnetic layer, to form a magnetic tunnel junction on the substrate.

Optionally, patterning the top electromagnetic material film, the first insulating film, the second insulating film, and the bottom electromagnetic material film includes: forming a patterned layer on the top electromagnetic material film, that the patterned layer exposes a portion of the top electromagnetic material film; and using the patterned layer as a mask, etching the top electromagnetic material film, the first insulating film, the second insulating film, and the bottom electromagnetic material film, until the surface of the substrate is exposed, to form the magnetic tunnel junction, that the magnetic tunnel junction includes: the bottom electromagnetic layer on the substrate, the second insulating layer on the bottom electromagnetic layer, the first insulating layer on the second insulating layer, and the top electromagnetic layer on the first insulating layer.

Another aspect of the present disclosure provides a semiconductor structure formed by the above-mentioned method, including: a substrate; and a magnetic tunnel junction on the substrate. The magnetic tunnel junction includes: a bottom electromagnetic layer on the substrate, a second insulating layer on the bottom electromagnetic layer, a first insulating layer on the second insulating layer, and a top electromagnetic layer on the first insulating layer.

Compared with existing technologies, the technical solutions of the embodiments of the present disclosure have the following beneficial effects.

In the method for forming the semiconductor structure provided by the technical solutions of the present disclosure, during a process of forming the first insulating film on the precursor film, since a material of the precursor film can block ions in a deposition process of forming the first insulating film from diffusing into the bottom electromagnetic material film, thereby preventing the deposition process of forming the first insulating film from affecting the bottom electromagnetic material film. At a same time, through the annealing treatment, the precursor film is formed into the second insulating film, and the second insulating film provides a material for forming a non-magnetic insulating layer in the magnetic tunnel junction. In summary, performance of the semiconductor structure formed by the method is improved.

Further, before forming the first insulating film, the precursor film has been formed on the bottom electromagnetic material film, so as to ensure that the precursor film can block the ions from diffusing into the bottom electromagnetic material film during the process of forming the first insulating film.

Further, a significance of selecting the thickness range of the insulating material film is that: if the thickness is less than about 0 angstroms, the ions can diffuse into the bottom electromagnetic material film during the deposition process of forming the first insulating film, resulting in poor performance of the formed semiconductor structure; and if the thickness is greater than about 500 angstroms, the deposition process of forming the insulating material film can still affect the bottom electromagnetic material film, which is not conducive to improving the performance of the formed semiconductor structure.

Further, by performing the oxidation treatment on the precursor film, the precursor film is formed into the first insulating film, and the thickness of the first insulating film is less than or equal to the thickness of the precursor film. The precursor film is used as a precursor layer to form the first insulating film, which save cost and process time. At a same time, process parameters of the oxidation treatment are controlled so that the thickness of the first insulating film is less than or equal to the thickness of the precursor film, during a process of forming the precursor film into the first insulating film. In other words, the process parameters of the oxidation treatment are controlled to ensure that the oxidation treatment of the precursor film is stopped, when a portion of the precursor film is left or the precursor film is formed into the first insulating film. Thus, influence of the oxidation treatment process on the bottom electromagnetic material film is avoided, so that the performance of the formed semiconductor structure is improved.

Furthermore, the annealing treatment can oxidize the material of the precursor film to form the second insulating film. The second insulating film and the first insulating film together serve as insulating layers for subsequently forming the magnetic tunnel junction. A process of oxidizing the precursor film is controlled by controlling a treatment time of the annealing treatment. Since an appropriate temperature of the annealing treatment is selected, an oxidation rate of the precursor film can be controlled. Thus, time parameters of the annealing process can be controlled, to oxidize the material of the precursor film to form the second insulating film, that is, to form the precursor film into the second insulating film with better insulating properties, while avoiding impact on the bottom electromagnetic material film, so that the performance of the formed semiconductor structure is improved.

Further, the temperature range of the annealing treatment is from about 300 degrees Celsius to about 400 degrees Celsius. A significance of selecting the temperature range is that: if the temperature is greater than about 400 degrees Celsius, the temperature is too high, that on one hand, it is easy to cause high temperature effects on materials, and on another hand, the temperature is too high, which is likely to cause the oxidation rate to be too fast, and is easy to cause over-oxidation of materials of the first insulating film and the second insulating film, resulting in a decrease in insulating performance of the first insulating film and the second insulating film; and if the temperature is less than about 300 degrees Celsius, the temperature is too low, resulting in too low efficiency of oxidizing the precursor film to form the second insulating film, which is not conducive to improving production efficiency.

### BRIEF DESCRIPTION OF THE DRAWINGS

The following accompanying drawings are merely examples for illustrative purposes according to various disclosed embodiments and are not intended to limit the scope of the present disclosure.

FIGS. 1 to 4 illustrate structures corresponding to certain stages during a fabrication process of a semiconductor structure;

FIGS. 5 to 15 illustrate structures corresponding to certain stages during an exemplary fabrication process of a semiconductor structure consistent with various disclosed embodiments of the present disclosure; and

FIG. 16 illustrates an exemplary fabrication process of a semiconductor structure consistent with various disclosed embodiments of the present disclosure.

### DETAILED DESCRIPTION

Reference will now be made in detail to exemplary embodiments of the present disclosure, which are illustrated in the accompanying drawings. Wherever possible, the same reference numbers will be used throughout the accompanying drawings to refer to the same or like parts.

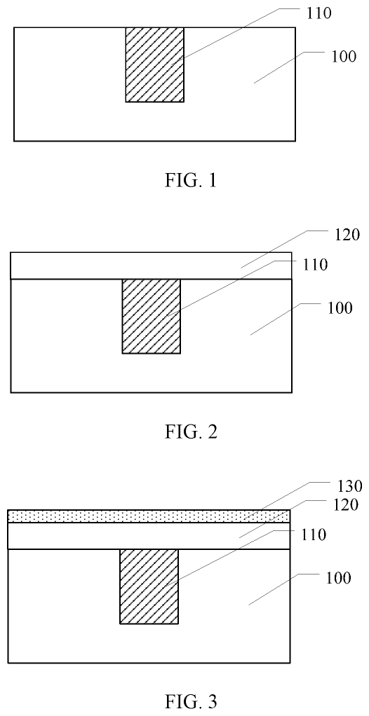

FIGS. 1 to 4 illustrate structures corresponding to certain stages during a fabrication process of a semiconductor structure.

Referring to FIG. 1, a substrate 100 is provided. A conductive layer 110 is provided in the substrate 100, and the substrate 100 exposes a surface of the conductive layer 110.

Referring to FIG. 2, a bottom electromagnetic material film 120 is formed on the substrate 100 and the surface of the conductive layer 110.

Referring to FIG. 3, an insulating film 130 is formed on the bottom electromagnetic material film 120.

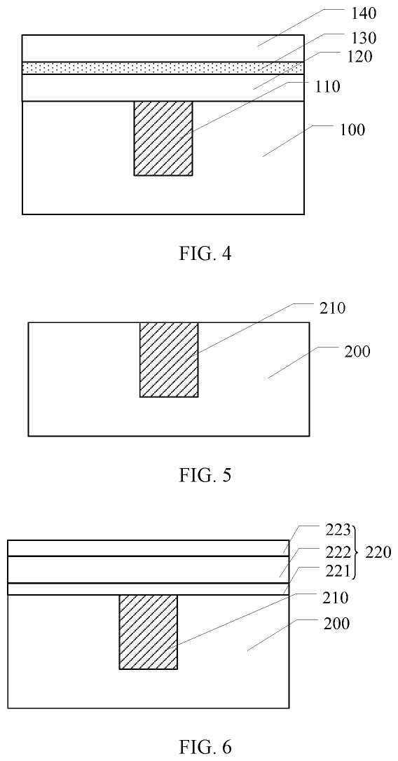

Referring to FIG. 4, a top electromagnetic material film 140 is formed on the insulating film 130.

The bottom electromagnetic material film 120 is formed on the substrate 100 and the surface of the conductive layer 110. The insulating film 130 is formed on the bottom electromagnetic material film 120. The top electromagnetic material film 140 is formed on the insulating film 130. The bottom electromagnetic material film 120, the insulating film 130, and the top electromagnetic material film 140 are used to form a magnetic tunnel junction.

However, since the insulating film 130 usually has a thickness, during a process of forming the insulating film 130, ions in a deposition process can diffuse into the bottom electromagnetic material film 120, resulting in influence on a material of the bottom electromagnetic material film 120. As a result, stability of the formed magnetic tunnel junction is poor, and the performance of the such semiconducting structure needs to be improved.

Embodiments of the present disclosure provide a method of forming a semiconductor structure, including: providing a substrate; forming a bottom electromagnetic material film on the substrate; forming a precursor film on the bottom electromagnetic material film; forming a first insulating film on the precursor film; performing an annealing treatment to form the precursor film into a second insulating film; and forming a top electromagnetic material film on the first insulating film. The performance of the semiconductor structure formed by the method is improved.

To make the above objectives, features and beneficial effects of the present disclosure clearer and more understandable, various exemplary embodiments of the present disclosure will be described in detail below with reference to the accompanying drawings.

FIGS. 5 to 15 illustrate structures corresponding to certain stages during an exemplary fabrication process of a semiconductor structure consistent with various disclosed embodiments of the present disclosure. FIG. 16 illustrates an exemplary fabrication process of a semiconductor structure consistent with various disclosed embodiments of the present disclosure.

Referring to FIG. 5, a substrate 200 is provided, according to S01 in FIG. 16.

In one embodiment, a conductive layer 210 is provided in the substrate 200, and the substrate 200 exposes a surface of the conductive layer 210.

In one embodiment, the substrate 200 includes: a semiconductor substrate (not shown in FIG. 5) and a dielectric layer (not shown in FIG. 5) on the semiconductor substrate, that the conductive layer 210 is in the dielectric layer.

The semiconductor substrate is made of a semiconductor material. In one embodiment, the semiconductor substrate is made of silicon. In other embodiments, the semiconductor substrate is made of a material including silicon carbide, silicon germanium, a compound semiconductor including Group III-V elements, silicon-on-insulator (SOI), germanium-on-insulator, or a combination thereof.

In one embodiment, device structures are provided in the semiconductor substrate, and the device structures include structures including PMOS transistors, NMOS transistors, CMOS transistors, resistors, capacitors, inductors, or a combination thereof.

The dielectric layer is made of a material including silicon oxide, a low-K dielectric material, an ultra-low-K dielectric material, or a combination thereof.

In one embodiment, the dielectric layer is made of silicon oxide.

The conductive layer 210 is made of a material including copper, tungsten, aluminum, titanium, titanium nitride, tantalum, or a combination thereof.

In one embodiment, the conductive layer 210 is made of copper.

Referring to FIG. 6, a bottom electromagnetic material film 220 is formed on the substrate 200, according to S02 in FIG. 16.

In one embodiment, the bottom electromagnetic material film 220 is formed on the substrate 200 and the surface of the conductive layer 210.

In one embodiment, the bottom electromagnetic material film 220 includes: a lower electrode film 221 on the substrate 200 and the surface of the conductive layer 210, a lower composite film 222 on the lower electrode film 221, and a lower electromagnetic film 223 on the lower composite film 222.

The lower electrode film 221 is made of a material including copper, tungsten, aluminum, titanium, titanium nitride, tantalum, or a combination thereof.

In one embodiment, the lower electrode film 221 is made of tantalum.

The lower composite film 222 has a structure including a single layer structure or a composite structure.

In one embodiment, the lower composite film 222 has the composite structure. The lower composite film 222 includes two conductive layers overlapped each other (not shown in FIG. 6), one layer of the two conductive layers is made of platinum, and another layer of the two conductive layers is made of cobalt.

In other embodiments, the conductive layers may also be made of a material including iron, platinum, cobalt, nickel, cobalt iron boron, cobalt iron, nickel iron, lanthanum strontium manganese oxygen, or a combination thereof.

The lower electromagnetic film 223 is made of a material including iron, platinum, cobalt, nickel, cobalt iron boron, cobalt iron, nickel iron, lanthanum strontium manganese oxygen, or a combination thereof.

In one embodiment, the lower electromagnetic film 223 has a single layer structure, and the lower electromagnetic film 223 is made of cobalt iron boron.

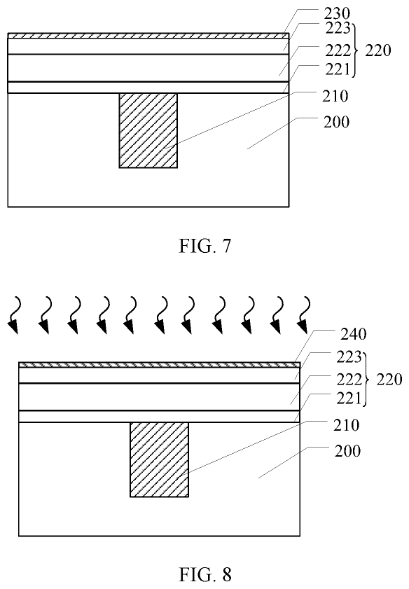

Next, a precursor film is formed on the bottom electromagnetic material film 220, according to S03 in FIG. 16. FIGS. 7-8 illustrate alternative exemplary processes of forming the precursor film.

Referring to FIG. 7, an insulating material film 230 is formed on the bottom electromagnetic material film 220, and the insulating material film 230 is made of a metal oxide.

The insulating material film 230 provides a material for subsequent formation of a precursor film.

A thickness of the insulating material film 230 ranges from about 0 angstroms to about 500 angstroms.

A preferred range of the thickness of the insulating material film 230 is from about 1 angstrom to about 100 angstroms.

A significance of the preferred range of the thickness of the insulating material film 230 being from about 1 angstrom to about 100 angstroms is that: if the thickness is less than about 1 angstrom, a thickness of the precursor film to be subsequently formed is too thin, and during a subsequent deposition and formation process of a first insulating film, the precursor film may not be able to block ions from diffusing into the bottom electromagnetic material film 220 at a bottom of the precursor film, resulting in poor performance of a formed semiconductor structure; and if the thickness is greater than about 100 angstroms, a process of forming the insulating material film may affect the bottom electromagnetic material film 220, which is not conducive to improving the performance of the formed semiconductor structure.

The metal oxide is a material including magnesium oxide, aluminum oxide, hafnium dioxide, zirconium dioxide, or a combination thereof.

In one embodiment, the insulating material film 230 is made of magnesium oxide.

Referring to FIG. 8, a modification treatment is performed on the insulating material film 230 to remove oxygen therefrom, to form the insulating material film 230 into a precursor film 240.

The precursor film 240 provides a material for subsequent formation of a second insulating film.

The modification treatment includes: performing a reduction treatment on the insulating material film 230 to remove oxygen therefrom.

Process parameters of the reduction treatment include: gases including hydrogen and helium, that a flow rate of the hydrogen is from about 50 SCCM to about 5000 SCCM, and a flow rate of the helium is from about 0 SCCM to about 10000 SCCM; a temperature from about 25 degrees Celsius to about 150 degrees Celsius; and a treatment time from about 1 second to about 120 minutes.

The precursor film 240 is made of a material including magnesium, aluminum, hafnium, zirconium, or a combination thereof.

In one embodiment, since the insulating material film 230 is made of magnesium oxide, the precursor film 240 formed after the modification treatment is made of magnesium.

Before subsequent formation of the first insulating film, the precursor film 240 has been formed on the bottom electromagnetic material film 220, so as to ensure that during the subsequent formation of the first insulating film, the precursor film 240 can block the ions from diffusing into the bottom electromagnetic material film 220.

In other embodiments, forming the precursor film 240 may also include a chemical vapor deposition process, a physical vapor deposition process, or a combination thereof.

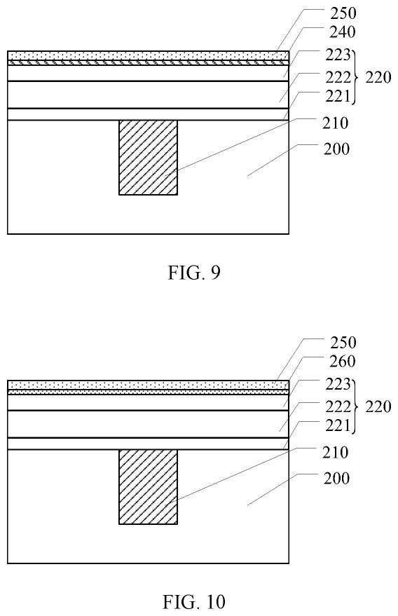

Referring to FIG. 9, a first insulating film 250 is formed on the precursor film 240, according to S04 in FIG. 16.

The first insulating film 250 and the subsequently formed second insulating film together provide materials for subsequent formation of a magnetic tunnel junction.

Forming the first insulating film 250 includes a chemical vapor deposition process, a physical vapor deposition process, an atomic layer deposition process, or a combination thereof.

The first insulating film 250 is made of a material including magnesium oxide, aluminum oxide, silicon nitride, silicon oxynitride, hafnium dioxide, zirconium dioxide, or a combination thereof.

In one embodiment, the first insulating film 250 and the insulating material film 230 are made of a same material, which is magnesium oxide.

In other embodiments, forming the first insulating film includes: performing an oxidation treatment on the precursor film to form the precursor film into the first insulating film, that a thickness of the first insulating film is less than or equal to a thickness of the precursor film, and the thickness of the first insulating film ranges from about 0 angstroms to about 500 angstroms.

The first insulating film is made of a material including magnesium oxide, aluminum oxide, hafnium dioxide, zirconium dioxide, or a combination thereof.

By performing the oxidation treatment on the precursor film, the precursor film is formed into the first insulating film, and the thickness of the first insulating film is less than or equal to the thickness of the precursor film. The precursor film is used as a precursor layer to form the first insulating film, which is beneficial to saving cost and process time. At a same time, process parameters of the oxidation treatment are controlled so that the thickness of the first insulating film is less than or equal to the thickness of the precursor film, during a process of forming the precursor film into the first insulating film. In other words, the process parameters of the oxidation treatment are controlled to ensure that the oxidation treatment on the precursor film is stopped, when a portion of the precursor film is left, or the precursor film is formed into the first insulating film. As a result, influence of the oxidation treatment process on the bottom electromagnetic material film can be avoided, so that the performance of the formed semiconductor structure is improved.

Referring to FIG. 10, an annealing treatment is performed to form the precursor film 240 into a second insulating film 260, according to S05 in FIG. 16.

Through the annealing treatment, the material of the precursor film 240 is oxidized to form the second insulating film 260 with better insulating performance.

A temperature range of the annealing treatment is from about 300 degrees Celsius to about 400 degrees Celsius.

A significance of selecting the temperature range is that: if a temperature is greater than about 400 degrees Celsius, the temperature is too high, that on one hand, it is easy to cause high temperature effects on a material of the bottom electromagnetic material film 220 and devices in the substrate 200, and on another hand, the temperature is too high, which is likely to cause an oxidation rate to be too fast, and is easy to cause over-oxidation of materials of the first insulating film 250 and the second insulating film 260, resulting in a decrease in insulating performance of the first insulating film 250 and the second insulating film 260; and if the temperature is less than about 300 degrees Celsius, the temperature is too low, resulting in too low efficiency of oxidizing the precursor film 240 to form the second insulating film 260, which is not conducive to improving production efficiency.

In one embodiment, the annealing treatment can also transform a material including an amorphous silicon oxide or a polycrystalline silicon oxide in the first insulating film 250 into a monocrystalline silicon oxide, which is beneficial to improving performance of the first insulating film 250, thereby improving the performance of the formed semiconductor structure.

A process of oxidizing the precursor film 240 is controlled by controlling a treatment time of the annealing treatment. When an appropriate temperature of the annealing treatment is selected, the oxidation rate of the precursor film 240 can be controlled. Thus, time parameters of the annealing process can be controlled, to oxidize the material of the precursor film 240 to form the second insulating film 260, that is, to form the precursor film 240 into the second insulating film 260 with better insulating properties, while avoiding impact on the bottom electromagnetic material film 220, so that the performance of the formed semiconductor structure is improved.

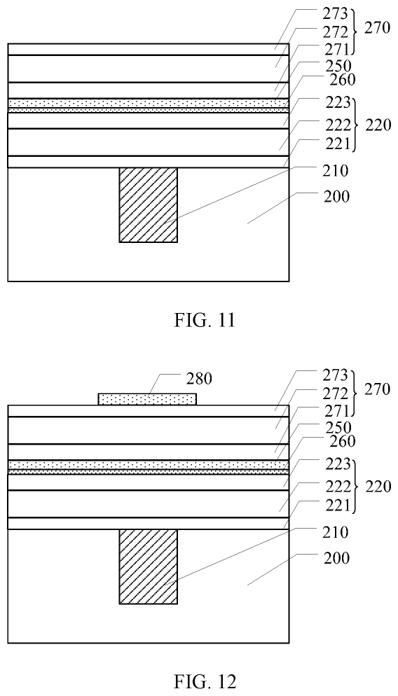

Referring to FIG. 11, after the second insulating film 260 is formed, a top electromagnetic material film 270 is formed on the first insulating film 250, according to S06 in FIG. 16.

The top electromagnetic material film 270 includes: an upper electromagnetic film 271 on the first insulating film 250, an upper composite film 272 on the upper electromagnetic film 271, and an upper electrode film 273 on the upper composite film 272.

The upper electromagnetic film 271 and the lower electromagnetic film 223 are made of a same material, which will not be repeated here.

The upper composite film 272 and the lower composite film 222 are made of a same material, which will not be repeated here.

The upper electrode film 273 and the lower electrode film 221 are made of a same material, which will not be repeated here.

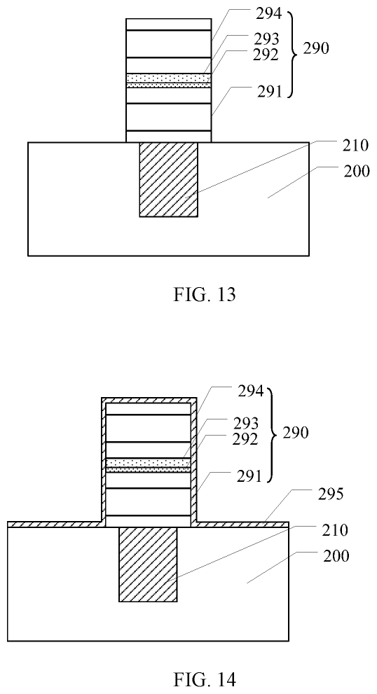

In one embodiment, after forming the top electromagnetic material film 270, the method further includes: patterning the top electromagnetic material film 270, the first insulating film 250, the second insulating film 260, and the bottom electromagnetic material film 220 until a surface of the substrate 200 is exposed, so that, the patterned top electromagnetic material film forms a top electromagnetic layer, the patterned first insulating film forms a first insulating layer, the patterned second insulating film forms a second insulating layer, and the patterned bottom electromagnetic material film forms a bottom electromagnetic layer, to form a magnetic tunnel junction on the substrate. FIGS. 12-13 illustrate alternative exemplary processes of forming the magnetic tunnel junction.

Referring to FIG. 12, a patterned layer 280 is formed on the top electromagnetic material film 270, and the patterned layer 280 exposes a portion of the top electromagnetic material film 270.

The patterned layer 280 is used as a mask for subsequent etching of the top electromagnetic material film 270, the first insulating film 250, the second insulating film 260, and the bottom electromagnetic material film 220.

In one embodiment, the patterned layer 280 covers the top electromagnetic material film 270 on the conductive layer 210, so that after a patterning process, a bottom of the formed magnetic tunnel junction is in contact with the surface of the conductive layer 210 to achieve electrical connection.

Referring to FIG. 13, using the patterned layer 280 as a mask, the top electromagnetic material film 270, the first insulating film 250, the second insulating film 260, and the bottom electromagnetic material film 220 are etched, until the surface of the substrate 200 is exposed, to form a magnetic tunnel junction 290.

The magnetic tunnel junction 290 includes a bottom electromagnetic layer 291 on the substrate 200, a second insulating layer 292 on the bottom electromagnetic layer 291, a first insulating layer 293 on the second insulating layer 292, and a top electromagnetic layer 294 on the first insulating layer 293.

In one embodiment, after forming the magnetic tunnel junction 290, the method further includes: removing the patterned layer 280.

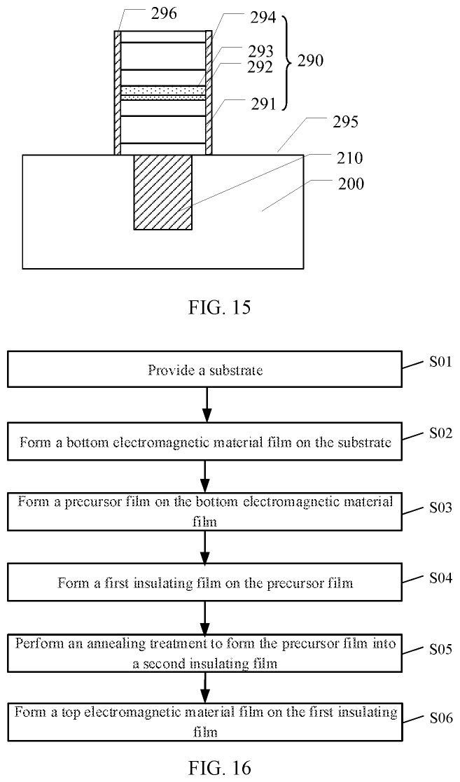

In one embodiment, the method for forming the semiconductor structure further includes: after forming the magnetic tunnel junction 290, forming sidewall spacers on sidewall surfaces of the magnetic tunnel junction 290, that the sidewall spacers are on the substrate. FIGS. 14-15 illustrate exemplary processes of forming the sidewall spacers.

Referring to FIG. 14, a sidewall material film 295 is formed on the substrate 200, and a top surface and the sidewall surfaces of the magnetic tunnel junction 290.

The sidewall material film 295 provides materials for subsequent formation of sidewall spacers.

Forming the sidewall material film 295 includes a chemical vapor deposition process, a physical vapor deposition process, an atomic layer deposition process, or a combination thereof.

In one embodiment, the sidewall material film 295 is formed by the atomic layer deposition process, so that thickness uniformity of the sidewall material film 295 formed is better, and step coverage is high, which facilitates subsequent formation of sidewall spacers with a uniform thickness.

The sidewall material film 295 is made of a material including silicon oxide, silicon nitride, silicon carbide nitride, silicon nitride boride, silicon oxynitride, silicon oxynitride, or a combination thereof.

In one embodiment, the sidewall material film 295 is made of silicon nitride.

Referring to FIG. 15, the sidewall material film 295 is etched back, until the surface of the substrate 200 and the top surface of the magnetic tunnel junction 290 are exposed, to form sidewall spacers 296.

The sidewall spacers 296 are used to protect the magnetic tunnel junction 290, reduce impact on the magnetic tunnel junction 290 from subsequent processes, and improve integrity of the magnetic tunnel junction 290, thereby improving stability of the magnetic tunnel junction 290.

Since the sidewall material film 295 is made of silicon nitride, correspondingly, the sidewall spacers 296 are made of silicon nitride.

Correspondingly, the embodiments of the present disclosure also provide a semiconductor structure formed by the above method.

The embodiments disclosed herein are exemplary only. Other applications, advantages, alternations, modifications, or equivalents to the disclosed embodiments that are obvious to those skilled in the art are intended to be encompassed within the scope of the present disclosure.

What is claimed is:

1. A method for forming a semiconductor structure, comprising:
providing a substrate;
forming a bottom electromagnetic material film on the substrate;
forming a precursor film on the bottom electromagnetic material film; and
forming a first insulating film on the precursor film.

2. The method according to claim 1, wherein:
the precursor film is made of a material including magnesium, aluminum, hafnium, zirconium, or a combination thereof.

3. The method according to claim 1, wherein forming the precursor film includes:
forming an insulating material film on the bottom electromagnetic material film, wherein the insulating material film is made of a metal oxide; and
performing a modification treatment on the insulating material film to remove oxygen therefrom, to form the insulating material film into the precursor film.

4. The method according to claim 3, wherein:
a thickness of the insulating material film ranges from about 0 angstroms to about 500 angstroms.

5. The method according to claim 3, wherein:
the metal oxide is a material including magnesium oxide, aluminum oxide, hafnium dioxide, zirconium dioxide, or a combination thereof.

6. The method according to claim 3, wherein:
forming the insulating material film includes a chemical vapor deposition process, a physical vapor deposition process, or a combination thereof.

7. The method according to claim 3, wherein the modification treatment includes:
performing a reduction treatment on the insulating material film to remove oxygen therefrom, wherein process parameters of the reduction treatment include:
gases including hydrogen and helium, wherein a flow rate of the hydrogen is from about 50 SCCM to about 5000 SCCM, and a flow rate of the helium is from about 0 SCCM to about 10000 SCCM;
a temperature from about 25 degrees Celsius to about 150 degrees Celsius; and
a treatment time from about 1 second to about 120 minutes.

8. The method according to claim 1, wherein:
forming the precursor film includes a chemical vapor deposition process, a physical vapor deposition process, or a combination thereof.

9. The method according to claim 1, wherein:
forming the first insulating film includes a chemical vapor deposition process, a physical vapor deposition process, an atomic layer deposition process, or a combination thereof; and
the first insulating film is made of a material including magnesium oxide, aluminum oxide, silicon nitride, silicon oxynitride, hafnium dioxide, zirconium dioxide, or a combination thereof.

10. The method according to claim 2, wherein forming the first insulating film includes:
performing an oxidation treatment on the precursor film, to form the precursor film into the first insulating film, wherein a thickness of the first insulating film is less than or equal to a thickness of the precursor film, and the thickness of the first insulating film ranges from about 0 angstroms to about 500 angstroms.

11. The method according to claim 10, wherein:
the first insulating film is made of a material including magnesium oxide, aluminum oxide, hafnium dioxide, zirconium dioxide, or a combination thereof.

12. The method according to claim 1, further comprising:
forming a top electromagnetic material film on the first insulating film; and
performing an annealing treatment before forming the top electromagnetic material film on the first insulating film, to form the precursor film into a second insulating film, wherein the second insulating film is at a bottom of the first insulating film, and a temperature range of the annealing treatment is from about 300 degrees Celsius to about 400 degrees Celsius.

13. The method according to claim 1, wherein:
a conductive layer is provided in the substrate, and the substrate exposes a surface of the conductive layer; and
the bottom electromagnetic material film is on the substrate and the surface of the conductive layer.

14. The method according to claim 1, wherein:
the bottom electromagnetic material film includes:
a lower electrode film on the substrate and the surface of the conductive layer,
a lower composite film on the lower electrode film, and
a lower electromagnetic film on the lower composite film.

15. The method according to claim 14, wherein:
the lower electrode film is made of a material including copper, tungsten, aluminum, titanium, titanium nitride, tantalum, or a combination thereof;
the lower composite film has a structure including a single layer structure or a composite structure; and
the lower electromagnetic film is made of a material including iron, platinum, cobalt, nickel, cobalt iron boron, cobalt iron, nickel iron, lanthanum strontium manganese oxygen, or a combination thereof.

16. The method according to claim 15, wherein:
when the lower composite film has the single layer structure, the lower composite film is made of a material including iron, platinum, cobalt, nickel, cobalt iron boron, cobalt iron, nickel iron, lanthanum strontium manganese oxygen, or a combination thereof; and
when the lower composite film has the composite structure, the lower composite film includes a plurality of conductive layers overlapped each other, and each layer of the plurality of conductive layers is made of a material including iron, platinum, cobalt, nickel, cobalt iron boron, cobalt iron, nickel iron, lanthanum strontium manganese oxygen, or a combination thereof.

17. The method according to claim 1, further comprising:
forming a top electromagnetic material film on the first insulating film, wherein the top electromagnetic material film includes:
an upper electromagnetic film on the first insulating film,
an upper composite film on the upper electromagnetic film, and
an upper electrode film on the upper composite film.

18. The method according to claim 12, further comprising:
after forming the top electromagnetic material film, patterning the top electromagnetic material film, the first insulating film, the second insulating film, and the bottom electromagnetic material film, until a surface of the substrate is exposed, so that the patterned top electromagnetic material film forms a top electromagnetic layer, the patterned first insulating film forms a first insulating layer, the patterned second insulating film forms a second insulating layer, and the patterned bottom electromagnetic material film forms a bottom electromagnetic layer, to form a magnetic tunnel junction on the substrate.

19. The method according to claim 18, wherein patterning the top electromagnetic material film, the first insulating film, the second insulating film, and the bottom electromagnetic material film includes:
forming a patterned layer on the top electromagnetic material film, wherein the patterned layer exposes a portion of the top electromagnetic material film; and
using the patterned layer as a mask, etching the top electromagnetic material film, the first insulating film, the second insulating film, and the bottom electromagnetic material film, until the surface of the substrate is exposed, to form the magnetic tunnel junction, wherein the magnetic tunnel junction includes:
the bottom electromagnetic layer on the substrate,
the second insulating layer on the bottom electromagnetic layer,
the first insulating layer on the second insulating layer, and
the top electromagnetic layer on the first insulating layer.

20. A semiconductor structure, comprising:
a substrate; and
a magnetic tunnel junction on the substrate, wherein the magnetic tunnel junction includes:
a bottom electromagnetic layer on the substrate,
a second insulating layer on the bottom electromagnetic layer,
a first insulating layer on the second insulating layer, and
a top electromagnetic layer on the first insulating layer.
